(19) United States
(12) Patent Application Publication
(10) Pub. No.: US 2002/0003888 A1
(43) Pub. Date: Jan. 10, 2002

(54) LONGITUDINALLY DIVIDED LOUDSPEAKER PORT WITH INCREASED AERODYNAMIC EFFICIENCY

(76) Inventor: TIERRY R. BUDGE, OREM, UT (US)

Correspondence Address: SCOTT C KRIEGER, KIRTON & MCCONKIE, 1800 EAGLE GATE TOWER, 60 EAST SOUTH TEMPLE, SALT LAKE CITY, UT, 84111

(21) Appl. No.: 09/405,295

(22) Filed: Sep. 23, 1999

(51) Int. Cl. H05K 5/00; G10K 13/00; H04R 1/02

(52) U.S. Cl. 381/345; 381/338; 381/349; 181/156; 181/160

(57) ABSTRACT

The present invention is an improved loudspeaker enclosure port with internal longitudinal dividers which help reduce turbulence in the port and control port selfresonance. Preferred embodiments of the present invention comprise a central circular tube or rod with radial dividers connecting the central tube to the internal wall of the port. The internal longitudinal dividers of the present invention are thought to reduce air friction losses in the port and to reduce cross-flow turbulence in the port yielding a more responsive speaker with more uniform aerodynamic drag on the driver diaphragm.

### THE FIELD OF THE INVENTION

The present invention relates to the field of high-quality audio loudspeakers with ported enclosures and more particularly to an aerodynamically-tuned loudspeaker enclosure port which improves airflow through the port thereby creating a more responsive speaker system. Vanes along the interior of the port help reduce friction losses in and around the port effectively reducing the dynamic impedance of the driver and increasing driver response and performance.

### BACKGROUND

Loudspeakers are essentially transducers which convert electrical energy into physical, acoustical energy. The design of typical basic loudspeakers has not changed for decades. Generally, a loudspeaker driver consists of a frame or housing, a cone or other diaphragm attached to a voice coil, a surround and spider suspension and a permanent magnet. Sound is created by moving the diaphragm to create sound waves in the air around the diaphragm. This is accomplished through electromagnetic attraction and repulsion of the voice coil. The outer periphery of the diaphragm is connected to the housing or frame by a flexible surround which allows the diaphragm to move freely and helps somewhat to keep the diaphragm and voice coil in proper alignment. The voice coil is typically a coil of wire which forms an inductor. As electrical current passes through the coil it produces a magnetic field. The voice coil is placed in close proximity to a permanent magnet which provides a permanent magnetic field which reacts with the variable magnetic field of the coil thereby causing the coil to be repelled or attracted according to the field of the coil and the polarity and magnitude of the coil current. The spider and surround keep the coil in precise alignment with the permanent magnet so that minute changes in current in the coil can accurately produce diaphragm movement and sound.

The physical characteristics of drivers can make them more suitable for reproducing sounds in certain frequency ranges. High frequency sound requires a driver that can react quickly, but which does not need a diaphragm that must displace a substantial distance. Low frequency sound requires a driver that can displace longer distances, but which does not need to react as quickly. Consequently, larger drivers, called woofers, are typically used to reproduce low frequency sound while very small, rigid drivers, called tweeters, are used for high frequency sound. A high-quality loudspeaker will generally have multiple drivers for reproducing sound in a variety of frequency ranges. Many loudspeakers will have at least a woofer, midrange and a tweeter to reproduce the entire audible sound spectrum, however, as the following disclosure will reveal, this can be achieved in other ways.

One problem inherent in typical driver design is the “backwave” created when the diaphragm rebounds from an extended position. This creates a sound wave which emanates from the back of the diaphragm which, if not controlled, may interfere with and even cancel the primary sound wave created by the diaphragm.

One method of dealing with backwave interference is to mount the driver in a sealed enclosure that will absorb the majority of the backwave preventing it from reaching the listener. This is commonly known as an “acoustic suspension” speaker. Another popular method of dealing with backwave emissions is to allow part of the wave to reach the listening area through a vent or port. This is known as a “bass reflex” design. Yet another method involves the use of a passive radiator or “drone driver” which vibrates with the backwave thereby absorbing energy and helping eliminate the backwave. All of these methods help somewhat to eliminate backwave interference, however they do so at the cost of lost energy and performance.

Backwave interference can also be dealt with using a multipolar speaker configuration. The typical multipolar system is a bipolar configuration which utilizes two identical drivers which are mounted in the front and back of a speaker enclosure. These two drivers are driven in-phase so that identical waves are emitted from the front and back of the enclosure. This eliminates the backwave cancellation problem because the waves are in-phase, but the drivers can suffer from a decreased response and lost energy due to the need to overcome increased pressure in the enclosure.

An additional problem with current speaker technology is caused by misalignment of the voice coil with the permanent magnet due to distortion of the diaphragm or cone. Driver surrounds and spiders must be flexible to provide the necessary response to electrical input, but this makes the driver diaphragm extremely susceptible to unequal air pressure across its surface area. As a diaphragm encounters unequal air pressure due to enclosure discontinuities or air flow patterns, the diaphragm distorts causing the attached voice coil to rotate off its central axis. This causes the precisely balanced magnetic fields of the permanent magnet and the voice coil to misalign thereby causing an inductive variance and increased current draw from the amplifier. This results in decreased power handling, poorer response and inaccurate reproduction of sound.

Another problem inherent in prior art speaker enclosure designs which limits low frequency response and the uniformity of response in the low frequency spectrum derives from aerodynamic friction losses in the speaker port and enclosure. Prior art designs do not fully take into account the drag on the speaker driver diaphragm caused by pressure changes in the speaker enclosure.

This problem presents itself most dramatically with large woofers which are driven to high output at low frequencies. Reproduction of low frequency sound requires a woofer diaphragm to displace a large quantity of air. Reproduction of low frequency sound at high volume levels requires that the sound waves be projected over some distance. This combination forces a driver diaphragm to move large quantities of air at fairly high speed. Even a relatively average-sized 10″ woofer has a diaphragm area of about 78 square inches. High quality woofer diaphragms can often displace over 1″ peak-to-peak. This combination of displacement and diaphragm area can easily yield air flow rates in excess of 50 cubic feet per minute (cfm). When this volume is forced through a port of about 2″ in diameter, the air velocity can exceed 2000 feet per minute or about 25 miles per hour. Air velocities and flow rates in this range can easily produce friction losses that can affect diaphragm response.

The air friction loss problem is exacerbated by the fact that driver diaphragms oscillate at high speed. A speaker enclosure port may have an outgoing air velocity of 2000feet per minute at one point in time and an equally high ingoing air velocityjust milliseconds later. These air flow oscillations in the port can produce constant port inlet and outlet losses and induce cross-turbulence in the port itself Inlet turbulence, outlet turbulence and in-port cross-turbulence create friction losses and also inhibit the development of laminar flow within the port.

Loudspeaker ports also exhibit a self-resonant effect also known as an “organ pipe effect” wherein the port acts to amplify a specific frequency. This resonant frequency of the port typically corresponds to the physical dimensions of the port as they relate to the wavelength of the resonant frequency. While this resonance may be used to counteract the decreased performance of the driver at the driver's resonant frequency it may also amplify signals unnecessarily causing a distortion of the sound output.

### SUMMARY AND OBJECTS OF THE INVENTION

The present invention comprises a loudspeaker with an enclosure and a port with internal vanes which reduce cross-turbulence within the port, remove or reduce port self-resonance and provide the loudspeaker with a more uniform response across the low frequency spectrum. The port of the present invention comprises internal longitudinal dividers or vanes within the port to guide the air flow in a longitudinal direction and prevent problems related to cross flow and associated cross-turbulence. The present invention is thought to decrease air friction losses in the port, especially those induced by cross flow in the port. The present invention is also thought to induce more laminar flow in the port thereby creating a more equal air resistance in both flow directions.

Accordingly, it is an object of a preferred embodiment of the present invention to provide a loudspeaker enclosure port with longitudinal dividers.

Another object of a preferred embodiment of the present invention is to provide a loudspeaker enclosure port which increases uniformity of speaker response.

A further object of a preferred embodiment of the present invention is to provide a loudspeaker enclosure with improved low frequency response.

Yet another object of a preferred embodiment of the present invention is to provide more uniform impedance with dynamic changes.

A once further object of a preferred embodiment of the present invention is to provide a reduction or elimination of port self-resonance.

### BRIEF DESCRIPTION OF THE DRAWINGS

In order that the manner in which the above-recited and other advantages and objects of the invention are obtained, a more particular description of the invention briefly described above will be rendered by reference to a specific embodiment thereof which is illustrated in the appended drawings. Understanding that these drawings depict only a typical embodiment of the invention and are not therefore to be considered to be limiting of its scope, the invention will be described and explained with additional specificity and detail through the use of the accompanying drawings in which:

FIG. 1 is a cross-sectional view of a loudspeaker and loudspeaker enclosure comprising an embodiment of the present invention.

FIG. 2 is a perspective view of a section of a preferred embodiment of the present invention.

FIG. 3 is an end view of a preferred embodiment of the present invention.

FIG. 4 is a longitudinal cross-sectional view of a preferred embodiment of the present invention.

FIG. 5 is a perspective view of a port of the present invention comprising multiple port sections.

FIG. 6 is an impedance vs. frequency graph showing the performance of a preferred embodiment of the present invention as compared to a conventional port.

### DETAILED DESCRIPTION OF THE PREFERRED EMBODIMENTS

In the following description, preferred embodiments of the present invention are described by referring to functional diagrams, schematic diagrams, functional flow charts, program flow charts and other graphic depictions which help to illustrate either the structure or processing of preferred embodiments used to implement the apparatus, system and method of the present invention. Using the diagrams and other depictions in this manner to present the invention should not be construed as limiting of its scope.

The port of the present invention may be used in a variety of loudspeaker types or designs including bass reflex, isobaric and other ported designs, however, it's advantages will be most apparent in highly responsive high-performance systems.

In reference to FIG. 1, a cross-section of an isobaric, multipolar loudspeaker is shown with loudspeaker enclosure 2 and isobaric chamber 4 which contains external driver 6 and internal driver 8. An acoustical chamber 10 directs the frontal output from internal driver 8 to the front of enclosure 2. In this particular embodiment, the novel port 12 of the present invention is placed at the forward end of acoustical chamber 10 where sound may emanate therefrom in the direction of a user. Port 12 may also be located at the rear of the enclosure or elsewhere. It should be noted that most other speaker designs using conventionally-tuned ports may benefit from the port design of the present invention and that the benefits of the present invention are not limited to the particular isobaric, multipolar design illustrated in FIG. 1 and used to demonstrate this preferred embodiment.

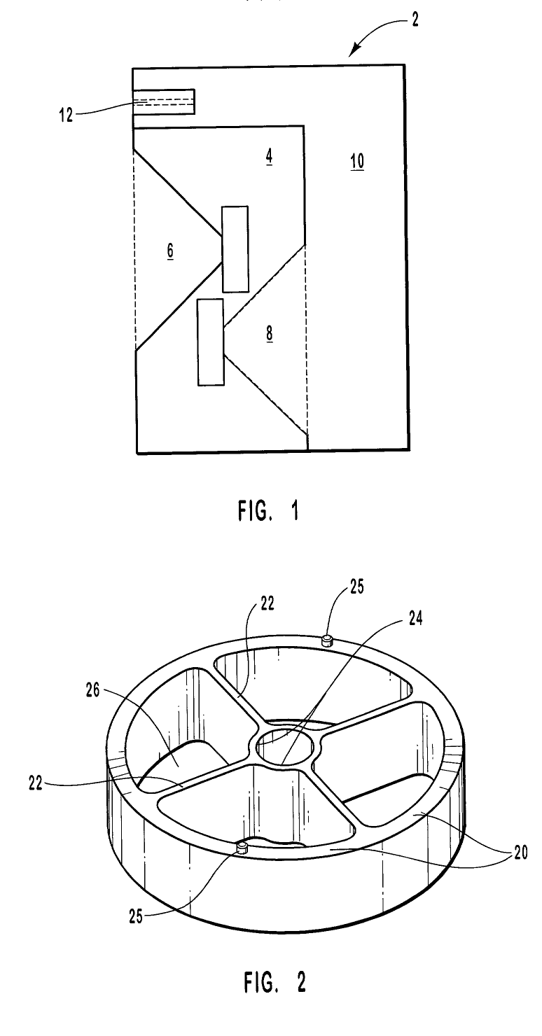

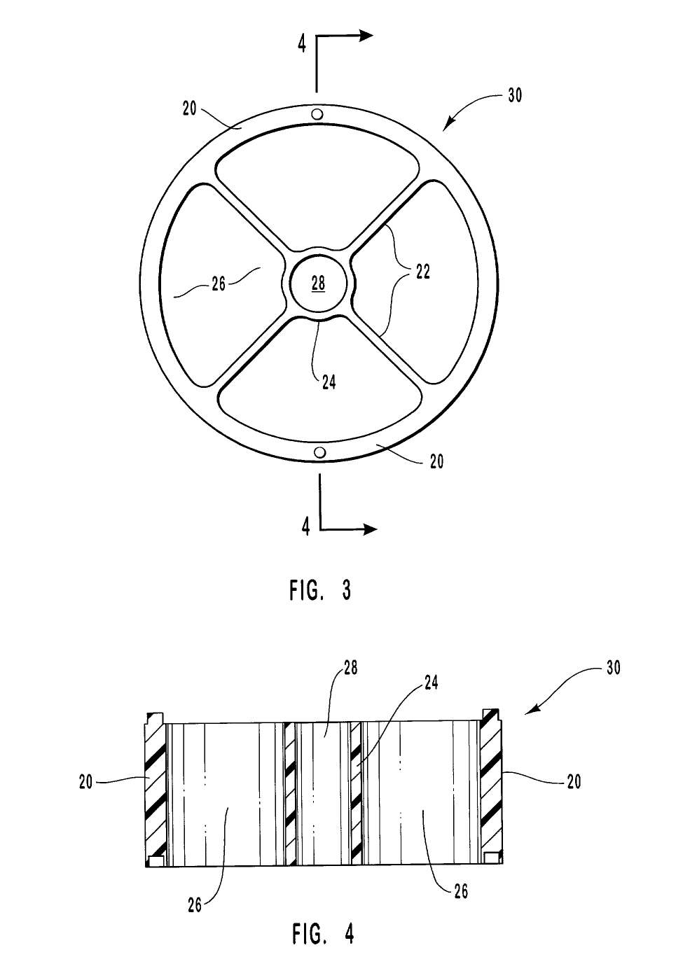

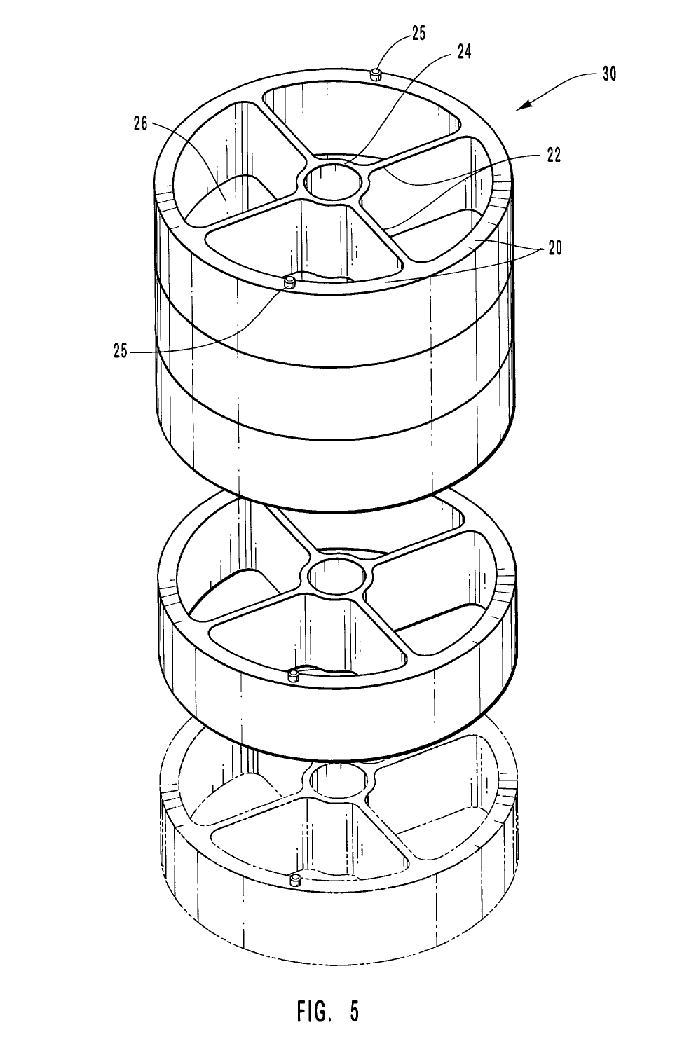

A preferred embodiment of the present invention, as shown in FIGS. 2-4, comprises an exterior perimeter wall 20 with internal longitudinal dividers 22 which divide the area of the port into distinct air channels 26 between which air currents may not cross. A circular concentric longitudinal divider 24 may also be used to divide the port into distinct channels. Perimeter wall 20 and internal longitudinal dividers 22 & 24 may be constructed of almost any solid material through which air flow is restricted. However, preferred materials will be smooth, with low coefficients of friction. Metal materials may be used, but plastics are preferred as they are more economical and more easily molded. A preferred method of making the present invention is injection molding of plastic materials.

The internal longitudinal dividers 22 & 24 of the present invention may be formed in myriad patterns and may form almost any number of air channels 26 so long as the port area is longitudinally subdivided into distinct air channels 26. Internal longitudinal dividers 22 & 24 may be formed as radial dividers 22 in a port of circular cross-section. They may also form concentric circles within the port as do concentric dividers 24. Other patterns may also be formed, for example and not by way of limitation, a honeycomb pattern, a grid of circular tubes, parallel linear dividers or sets of parallel dividers forming a grid pattern. Any of these patterns will form air channels 26 with numerous cross-sectional shapes each of which serves the purpose of dividing the port air flow into separate longitudinal segments. However, it has been found that performance declines when the port cross-sectional area is divided into air channels with a cross-sectional area less than . 10 square inches. Preferred embodiments of the present invention utilize air channels 26 with asymmetrical shapes which are thought to reduce the generation of standing waves and associated “organ-pipe” effects.

The preferred embodiment of the present invention shown in FIGS. 2-5 is a modular, sectionalized port made up of short sections of approximately 0.25 to 1 inch in length. Any section length may be manufactured to obtain a desired final port length. These sections 30 are joined together to form a port of the proper length for a given application. This production technique allows the use of a standard port component for multiple applications. Port sections which are made of plastic material may be joined with a snap-fit configuration, with plastic cement or other adhesives or with other bonding techniques. The present invention may also be constructed in a single unit without modular sections.

It should be noted that the exterior perimeter wall 20 of the present invention may also be formed in a variety of shapes. For example and not by way of limitation, exterior wall 20 may be formed in a square, triangular, circular, trapezoidal, ellipsoidal, rectangular or other shape.

In a preferred embodiment of the present invention, as shown in FIGS. 2-4, the exterior perimeter wall 20 is circular in cross-section with an outside diameter of 2.375″ and an inside diameter of 2.125″. Internal longitudinal dividers 22 which are radial in configuration have a thickness of 0.06″ and extend from the inside surface of perimeter wall 20 to the outer surface of concentric divider 24. Concentric divider 24 has an outside diameter of 0.5″ and an inside diameter of 0.375″. In this preferred embodiment, a cap is placed on the end of central air channel 28 and it does not contribute to the air flow of the port. In this manner, ports with excessive cross-sectional area may have their air channels capped to improve performance or increase aesthetic characteristics of the port.

In reference to FIG. 5, the assembly of modular port sections to achieve a desired port length can be seen. Alignment pins 25 ensure proper alignment of modular sections so that longitudinal dividers are continuous throughout the port.

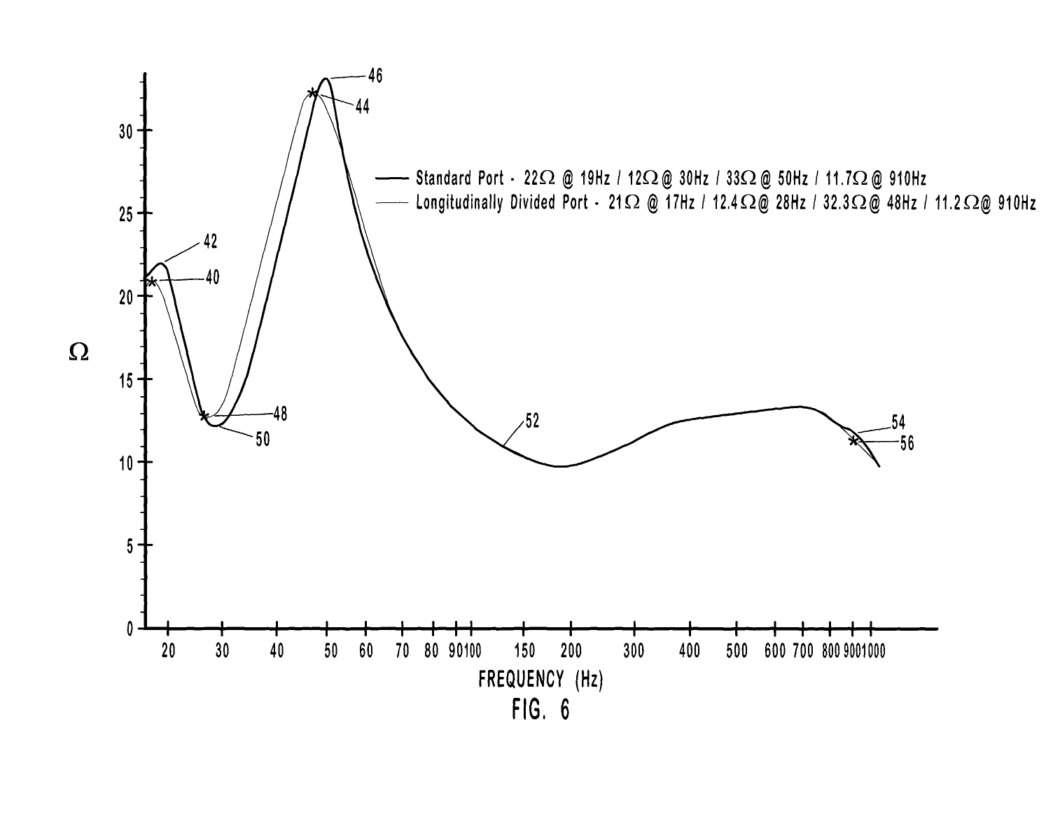

The advantages of the present invention may be seen with reference to FIG. 6 which shows an impedance vs. frequency curve for a bipolar, isobaric loudspeaker, such as is shown in FIG. 1. FIG. 6 shows a graph of the frequency/impedance curve for a loudspeaker with a standard open port having a circular cross-section as well as a frequency/impedance curve fort he same loud speaker using the port of the present invention.

Apparent in FIG. 6 is a significantly flatter response in the low frequency range for the port of the present invention. The prior art open port realizes a trough 50 with a value of 12 ohms at 30 Hz. and a higher peak 46 with a value of 33 ohms at 50 Hz. These values yield an impedance spread of 21 ohms between higher peak 46 and trough 50. The port of the present invention realizes a trough 48 with a value of 12.4 ohms at 28 Hz. and a higher peak 44 of 32.3 ohms at 48 Hz. Thereby yielding an impedance spread of 19.9 ohms. This flatter response curve at low frequencies allows the loudspeaker to better reproduce sound without distortion.

Another advantage of the present invention apparent in the data of FIG. 6, is the lower cutoff frequency achieved through the use of the present invention. The trough realized through the use of a prior art port results in a trough frequency, typically the cutoff frequency, of 30 Hz 50 while the use of the port of the present invention in the same loudspeaker results in a trough frequency of 28 Hz. thereby lowering the cutoff frequency achieved in a conventional loudspeaker and increasing the range of the loudspeaker.

A variety of factors are involved in the design of a prior art open port. Enclosure volume, the resonant frequency of the drivers, the desired resonant frequency for the enclosure and the port diameter are all factors in port design. Various known equations are used to determine port length and other characteristics. However, once the dimensions of a typical open port are set, the port will have a characteristic resonant frequency at which loudspeaker output will be reinforced. While this phenomenon will increase loudspeaker output at the port's resonant frequency, this effect is detrimental to the accurate reproduction of sound because sounds in the port's resonant frequency range will be unnaturally magnified. The port of the present invention avoids this unwanted magnification as shown in FIG. 6 where the loudspeaker with a typical open port has a magnified output and increased impedance of 11.7 ohms 54 at 910 Hz and the port of the present invention results in an impedance of 11.2 ohms 56 at the same frequency thereby yielding a more linear curve and more predictable and natural response.

The present invention may be embodied in other specific forms without departing from its spirit or essential characteristics. The described embodiments are to be considered in all respects only as illustrated and not restrictive. The scope of the invention is, therefore, indicated by the appended claims rather than by the foregoing description. All changes which come within the meaning and range of equivalency of the claims are to be embraced within their scope.

what is claimed is:

1. A loudspeaker enclosure port comprising:
an elongated tube; and
one or more internal longitudinal dividers within said tube.

2. The loudspeaker enclosure port of claim 1 wherein said tube has a circular cross-section.

3. The loudspeaker enclosure port of claim 1 wherein said tube contains four of said dividers.

4. The loudspeaker enclosure port of claim 1 wherein one or more of said dividers is a divider tube with a circular cross-section.

5. The loudspeaker enclosure port of claim 4 further comprising radial longitudinal dividers which divide the area between said divider tube and said elongated tube.

6. A loudspeaker port comprising:
driver means;
means for enclosing said driver means having an interior space and an exterior space;
means for air passage between said interior space and said exterior space; and
means for reducing air turbulence in said means for air passage.

7. The loudspeaker enclosure port of claim 6 wherein said means for reducing air turbulence comprises a means for reducing cross-flow within said means for air passage.

8. The loudspeaker enclosure port of claim 6 wherein said means for reducing air friction comprises a means for reducing transverse eddy currents within said means for air passage.

9. A loudspeaker apparatus comprising:
a loudspeaker enclosure;
at least one driver;
a port between said enclosure and an exterior space, said port comprising an elongated tube with longitudinal dividers which divide the area within said tube into longitudinal spaces.

10. The loudspeaker apparatus of claim 9 wherein said dividers comprise a tubular divider with a circular cross section surrounded by radial dividers which divide the space between said tubular divider and said port.

11. A loudspeaker apparatus comprising:
at least one loudspeaker enclosure;
at least one isobaric chamber;
at least one acoustical chamber;
one or more pairs of substantially identical drivers, each pair comprising a first driver and a second driver, said drivers mounted in said isobaric chamber such that the output of said first drivers is directed into an exterior space and the output of said second drivers is directed into said acoustical chamber; and
at least one port forming an opening between said acoustical chamber and said exterior space, said at least one port being comprised of at least one hollow tubular structure with one or more internal longitudinal dividers.

12. The loudspeaker apparatus of claim 11 wherein said hollow tubular structure has a circular cross-section and one or more of said longitudinal dividers is a tubular divider with a circular cross-section and further comprising one or more radial dividers.

13. The loudspeaker apparatus of claim 12 wherein said tubular divider is concentric with said hollow tubular structure.
